(19) United States
(12) Patent Application Publication
(10) Pub. No.: US 2014/0095087 A1
(43) Pub. Date: Apr. 3, 2014

(54) METHOD FOR GENERATING A FAULT SIGNAL

(71) Applicant: SIEMENS AKTIENGESELLSCHAFT, MUENCHEN (DE)

(72) Inventors: Daniel Bejmert, Walbrzych (PL); Waldemar Rebizant, Wroclaw (PL); Ludwig Schiel, Berlin (DE); Andrzej Wiszniewski, Wroclaw (PL)

(21) Appl. No.: 14/118,614

(22) PCT Filed: May 19, 2011
(86) PCT No.: PCT/EP2011/058131

§ 371 Date: Nov. 19, 2013

(51) Int. Cl. G01R 31/02

(52) U.S. Cl. CPC G01R 31/025
USPC 702/58

(57) ABSTRACT

A method generates a fault signal that displays whether an internal transformer fault is present. According to the method, a differential current signal that indicates the difference between the primary current and the secondary current of the transformer, taking into consideration the conversion ratio of the transformer, is ascertained. A plurality of different criteria signals are generated using the differential current signal. At least two individual fuzzy matching functions are assigned to each criteria signal. The fuzzy matching functions are analyzed, thereby generating the fault signal.

The invention relates to a method for generating a fault signal which indicates whether or not an internal transformer fault exists.

When transformers are switched on, significant magnetization currents can arise. Depending on the conversion ratio of the transformer, these magnetization currents cause current differences between the primary side of the transformer and the secondary side of the transformer so that protective devices which are assigned to the transformer can be caused to actuate without a fault actually having arisen or switching off being necessary. The problem therefore arises of deciding between switching-on processes and internal faults; the latter is made all the more difficult if current transformer saturation also occurs in the instrument transformers assigned for detecting the transformer currents.

In order to improve the stabilization of the protective functions when transformers are switched on, in the case of a known differential protection device from Siemens AG which is marketed under the product name SIPROTEC 7UT613/63X, the second harmonic of the current is evaluated.

The document “Performance analysis of traditional and improved transformer differential protective relays” (Guzmán A., Altuve, Hector J., SEL Technical Papers, 2000, pp. 405-412) discloses a method wherein the even harmonics of the differential current, the fifth harmonic and the direct current portion of the differential current are evaluated in order to be able to detect inrush currents.

The document “A new method to identify inrush current based on error estimation” (He B., Zhang X., Bo Z., IEEE Transactions on Power Delivery, Vol. 21, No. 3, July 2006, pp. 1163-1168) discloses a method for differentiating internal transformer faults and inrush currents, wherein the actual curve shape of the differential current is compared with reference waveforms. Two different frequency conditions are used per half-wave.

The document “A new principle of discrimination between inrush current and internal fault current of transformer based on self-correction function” (Zengping W., Jing M., Yan X., Lei M., The 7th International Power Engineering Conference, Singapore, November 2005, Vol. 2, pp. 614-617) discloses a correlation method wherein fault currents are differentiated from inrush currents in that a waveform correlation coefficient for the relation between the first half-wave and the successive half-wave of the differential current is generated and evaluated.

The document “Correlation analysis of waveforms in non-saturation zone-based method to identify the magnetizing inrush in transformer” (Bi D. Q., Zhang X. A., Yang H. H., Yu G. W., Wang X. H., Wang W. J., IEEE Transactions on Power Delivery, Vol. 22, No. 3, July 2007, pp. 1380-1385) discloses a stabilization algorithm which is based on correlation coefficients which define the correlation between the waveform of the differential current in the non-saturation case and two sinusoidal waveforms.

The document “A self-organizing fuzzy logic based protective relay—an application to power transformer protection” (IEEE Trans. Power Delivery vol. 12, No. 3, 1997, pp. 1119-1127) discloses a fuzzy logic method wherein different criterion signals are fuzzified and provided with weighting factors in order to be able to differentiate between inrush currents and fault currents.

The document “Fuzzy logic-based relaying for large power transformer protection” (Myong-Chul S., Chul-Won P., Jong-Hyung K., IEEE Transaction on Power Delivery, Vol. 18, No. 3, July 2003, pp. 718-724) discloses a further fuzzy-based differential protection system for transformers.

The object underlying the invention is to provide a method for generating a fault signal which indicates particularly reliably whether an internal transformer fault has occurred or not.

This object is achieved according to the invention with a method having the features of claim 1. Advantageous embodiments of the method according to the invention are disclosed in the subclaims.

According to the invention, a method is provided by which a differential current signal which indicates the difference between the primary current and—taking account of the conversion ratio of the transformer—the secondary current of the transformer, is ascertained and a plurality of different criteria signals is generated using the differential current signal, at least two individual fuzzy membership functions are assigned to each criterion signal and the fuzzy membership functions are evaluated, thereby generating the fault signal.

An essential advantage of the method according to the invention is that, due to the use of at least two individual fuzzy membership functions per criterion signal, it can be determined very precisely whether a transformer fault has occurred or not.

It is considered advantageous if three decision paths are formed, to each of which one or more of the fuzzy membership functions are assigned in each case and in each of the three decision paths, the fuzzy membership functions are each evaluated, thereby generating a logical binary signal, wherein each binary signal indicates, according to the relevant test result of the respective decision path, whether an internal transformer fault has occurred or not and the logical binary signals are subjected to a logical operation, thereby generating the fault signal.

The fault signal is preferably generated by a logical OR operation with the logical binary signals.

In a preferred embodiment of the method, it is provided that at least the fuzzy membership functions of a criterion signal can also be assigned to at least one of the decision paths, for example, a first decision path, said criterion signal relating to the ratio K_{d1h}=I_{d1h}/Iₙ of the fundamental I_{d1h} of the differential current to the nominal current Iₙ of the transformer, and the logical binary signal of this decision path is generated with this fuzzy membership function.

Furthermore, the fuzzy membership functions of criterion signals can also be assigned to the first decision path, said criterion signals relating to the ratio Kᵣ₂ₕ=I_{d2h}/I_{d1h} of the 2nd harmonic I_{d2h} to the fundamental I_{d1h} in the differential current and/or to the ratio K_{DCoff}=I_{rDCoff}/I_{d1h} of the reconstructed DC component I_{rDCoff} to the fundamental I_{d1h} in the differential current.

In a further preferred embodiment of the method, it is provided that at least the fuzzy membership functions of a criterion signal are also assigned to at least one of the decision paths, for example, a second decision path, said criterion signal relating to the deformation coefficient D_{1d} of the differential current in the non-saturation time interval of the differential current for the detection of winding faults at small differential currents, and the logical binary signal of said decision path is generated with this fuzzy membership function.

Furthermore, the fuzzy membership functions of criterion signals can also be assigned to the second decision path, said criterion signals relating to the ratio K_{DCon}=I_{rDCon}/I_{d1h} of the calculated DC component I_{rDCon} to the fundamental I_{d1h} in the differential current and/or to the ratio Kᵣ₂ₕ=I_{d2h}/I_{d1h} of the 2nd harmonic I_{d2h} to the fundamental I_{d1h} in the differential current.

In a further preferred embodiment of the method, it is provided that at least the fuzzy membership functions of a criterion signal can also be assigned to at least one of the decision paths, for example, a third decision path, said criterion signal relating to the deformation coefficient D_{2d} of the differential current in the non-saturation time interval of the differential current for rapid fault detection at large differential currents, and the logical binary signal of this decision path is generated with these fuzzy membership functions.

In a particularly preferred embodiment of the method, it is provided that three decision paths are formed, to each of which one or more of the fuzzy membership functions are assigned, wherein at least the fuzzy membership functions of one criterion signal are also assigned to a first decision path, said criterion signal relating to the ratio K_{d1h} of the fundamental I_{d1h} of the differential current to the nominal current Iₙ of the transformer, and for said first decision path, a first logical binary signal is generated which indicates whether, according to the test result of the first decision path, an internal transformer fault has occurred or not, at least the fuzzy membership functions of a criterion signal are also assigned to a second decision path, said criterion signal relating to the deformation coefficient D_{1d} of the differential current in the non-saturation time interval of the differential current for the detection of winding faults at small differential currents, and for this second decision path, a second logical binary signal is generated which indicates whether, according to the test result of the second decision path, an internal transformer fault has occurred or not, at least the fuzzy membership functions of a criterion signal are also assigned to a third decision path, said criterion signal relating to the deformation coefficient D_{2d} of the differential current in the non-saturation time interval of the differential current for rapid fault detection at large differential currents and for this third decision path, a third logical binary signal is generated which indicates whether, according to the test result of the third decision path, an internal transformer fault has occurred or not.

The fault signal is preferably generated in the case of the latter by a logical OR operation with the first, second and third logical binary signals.

The invention also relates to a differential protection device for protecting a transformer. According to the invention, a computer device and a memory store are provided, wherein a program for controlling the computer device is stored in the memory store and wherein, during execution by the computer device, the program carries out a method for generating a fault signal as described above.

The invention will now be described in greater detail by reference to exemplary embodiments which are illustrated in the drawings, in which:

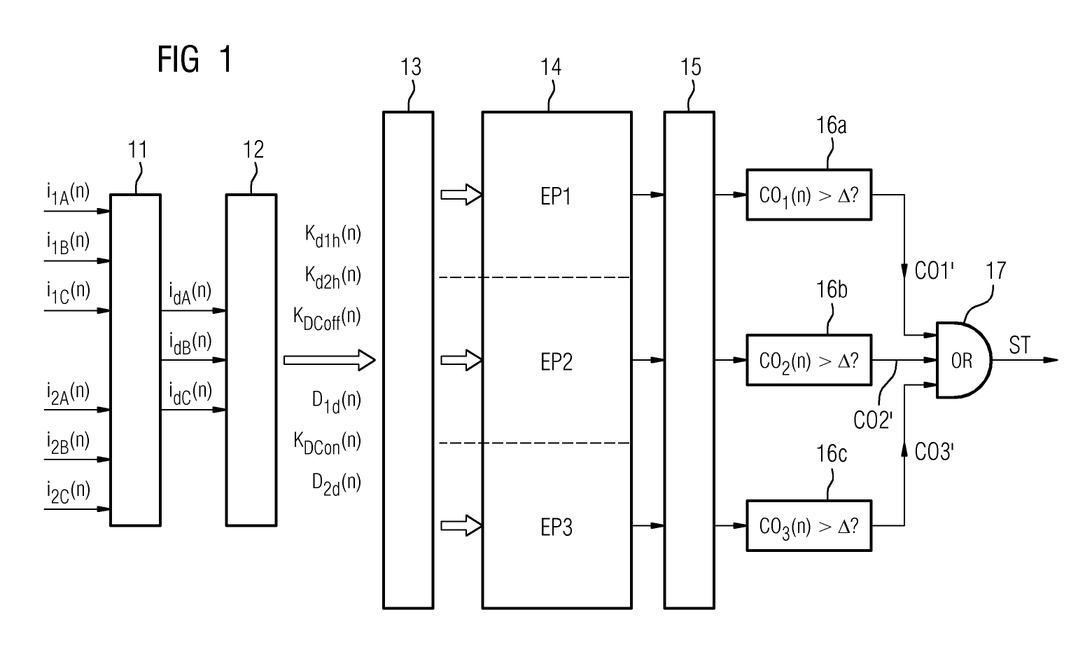

FIG. 1 is a block circuit diagram of an exemplary embodiment of an arrangement with which the method according to the invention can be carried out,

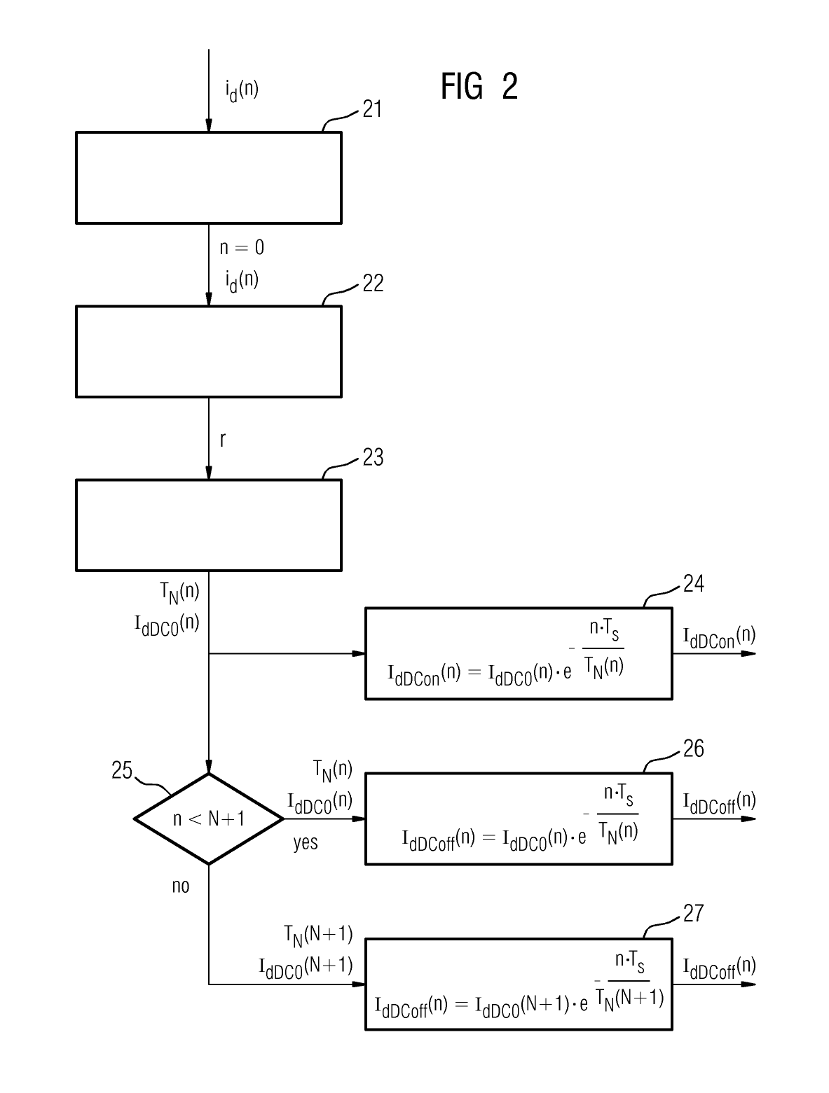

FIG. 2 is a block circuit diagram of an exemplary embodiment for determining direct current components,

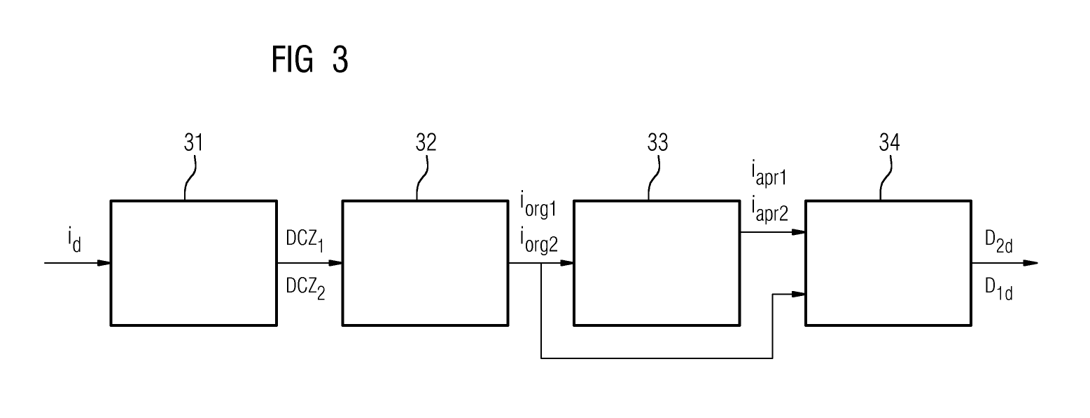

FIG. 3 is a block circuit diagram for calculating the disturbance coefficients in the non-saturation interval,

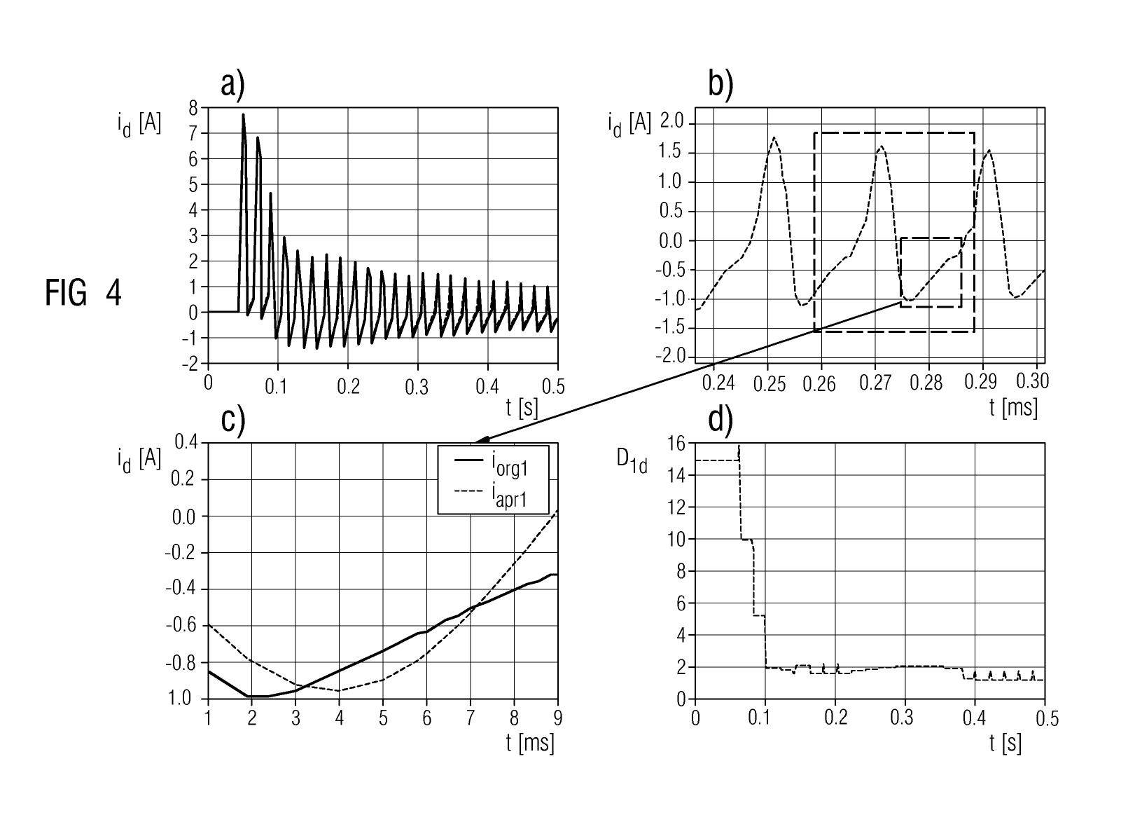

FIG. 4 is an exemplary illustration of the variation over time of the differential current and the deformation coefficient (disturbance coefficient) D_{1d},

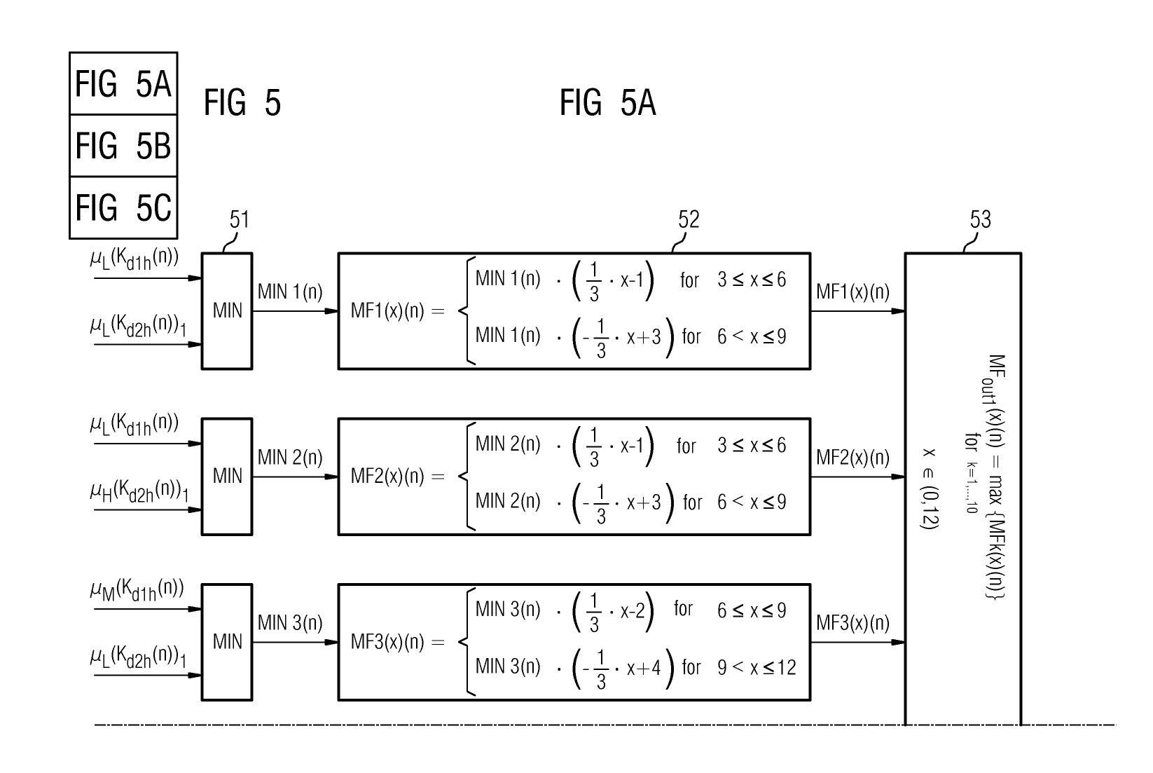

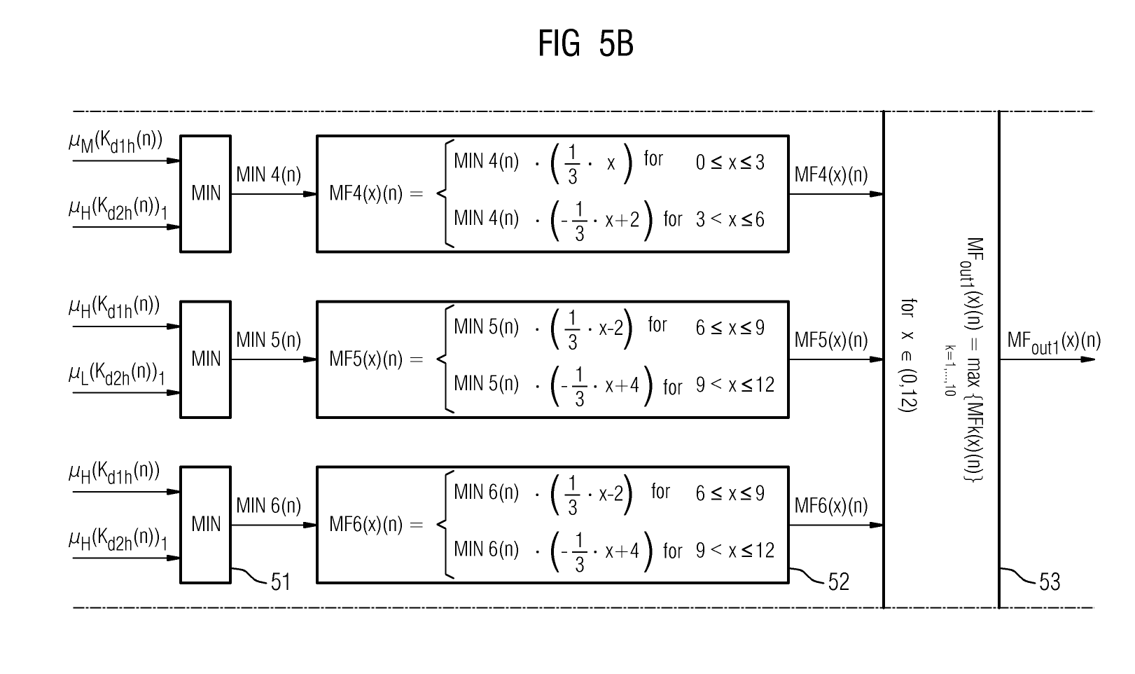

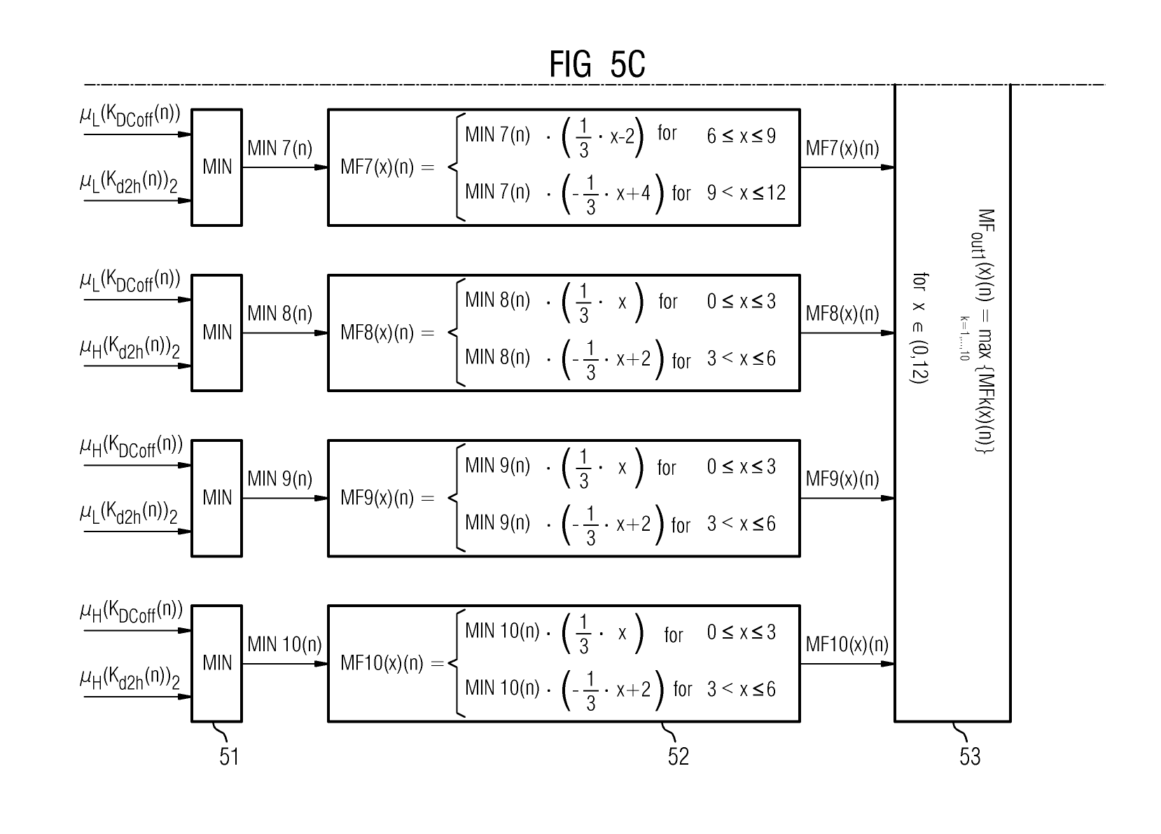

FIG. 5 is a block circuit diagram for the upper decision path of the arrangement of FIG. 1,

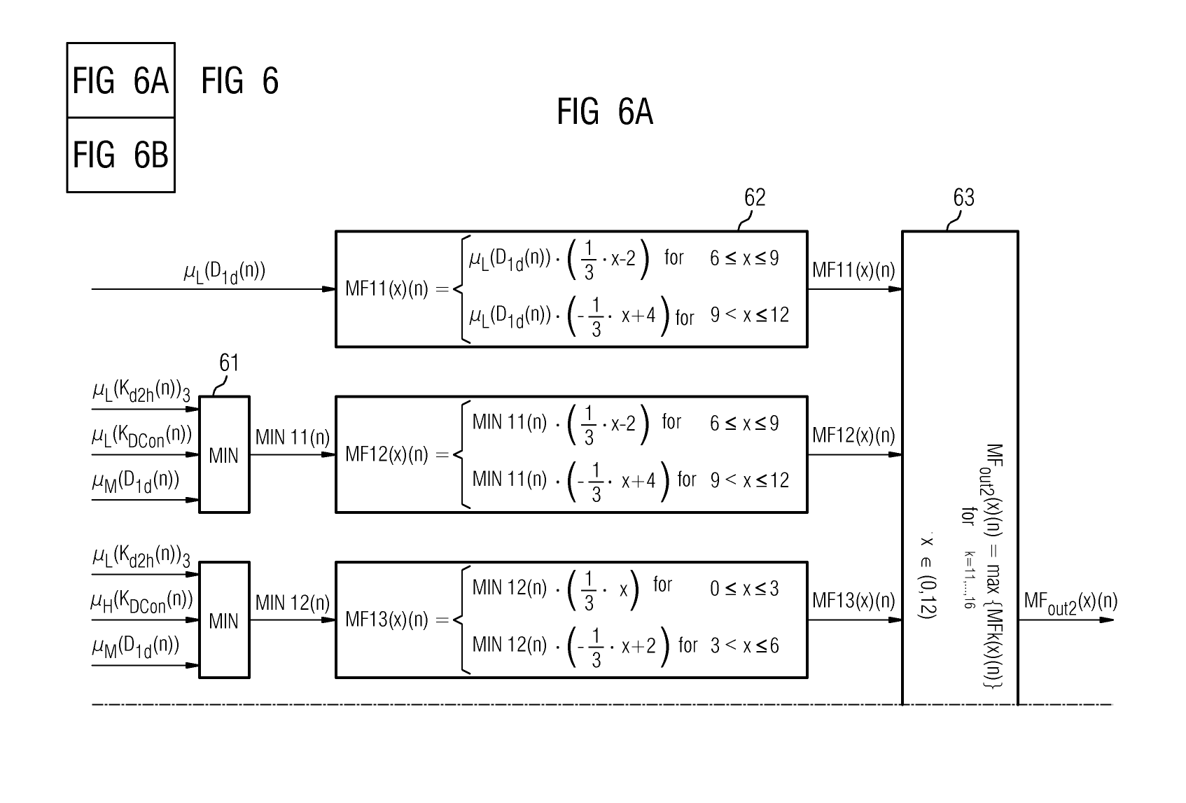

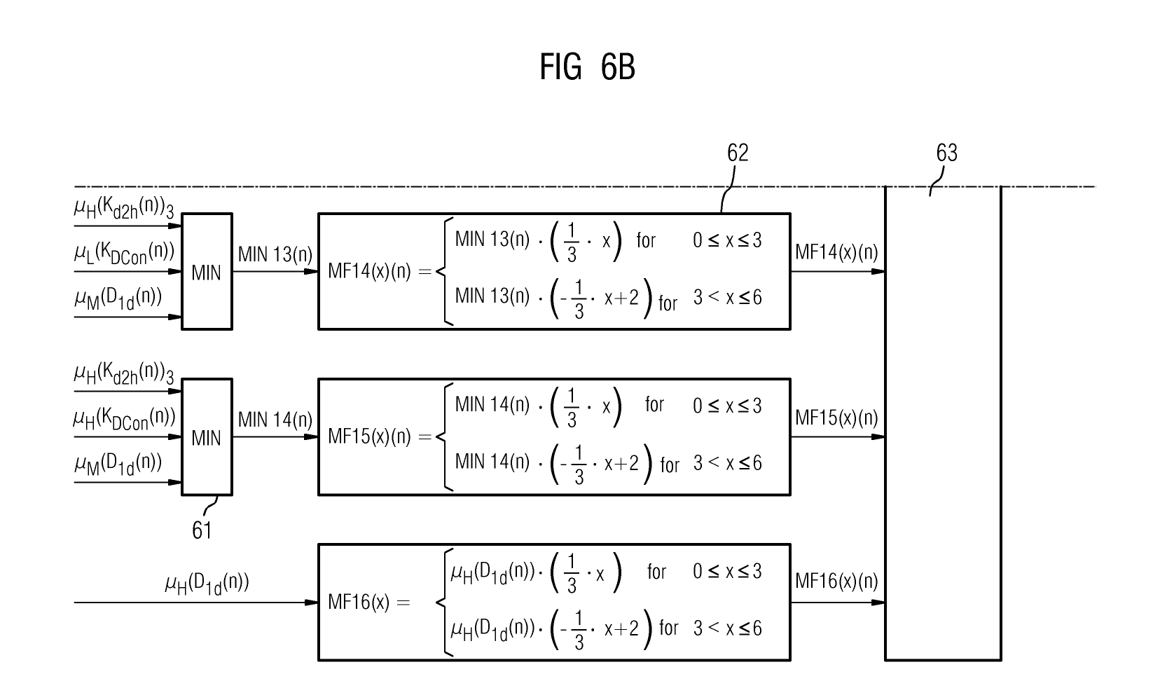

FIG. 6 is a block circuit diagram for the middle decision path of the arrangement of FIG. 1,

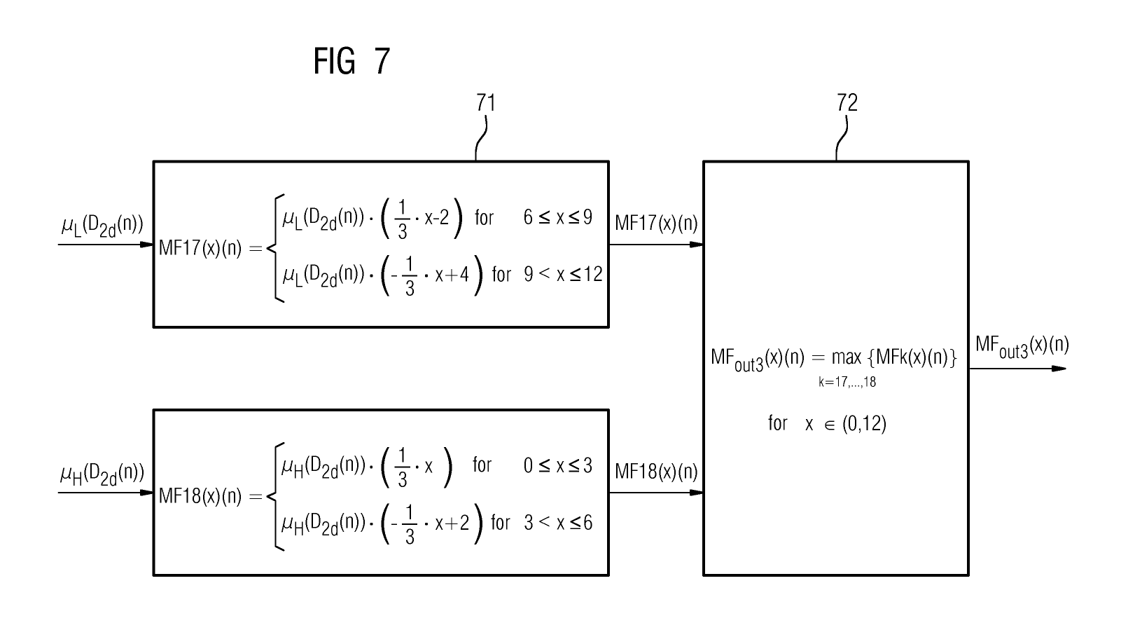

FIG. 7 is a block circuit diagram for the lower decision path of the arrangement of FIG. 1,

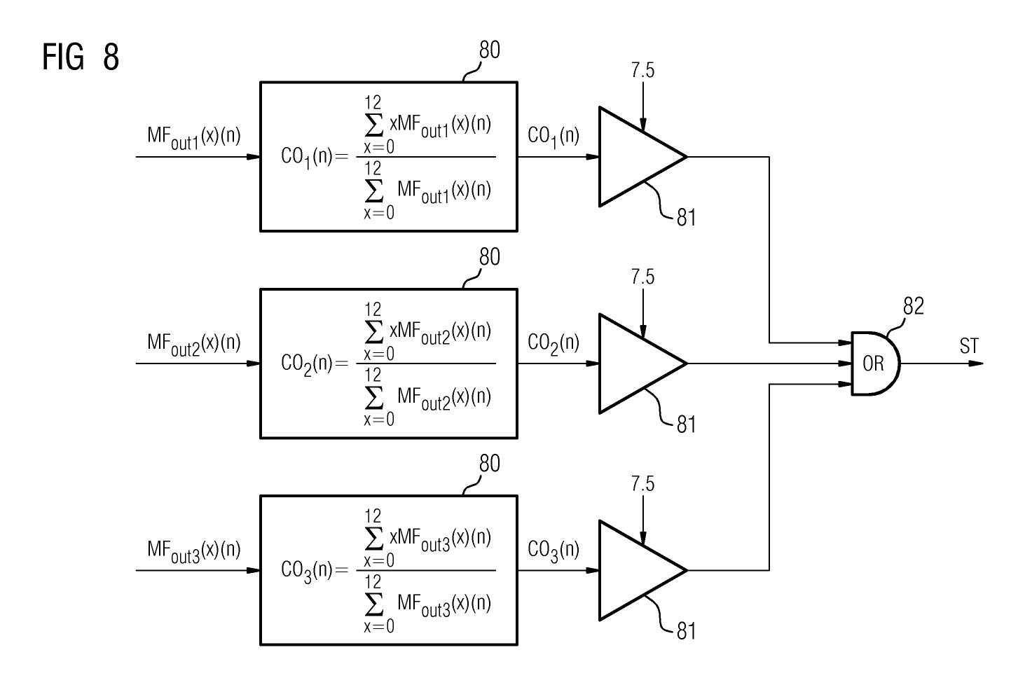

FIG. 8 is a block circuit diagram for the evaluation of the results of the three decision paths as per FIG. 1, in greater detail,

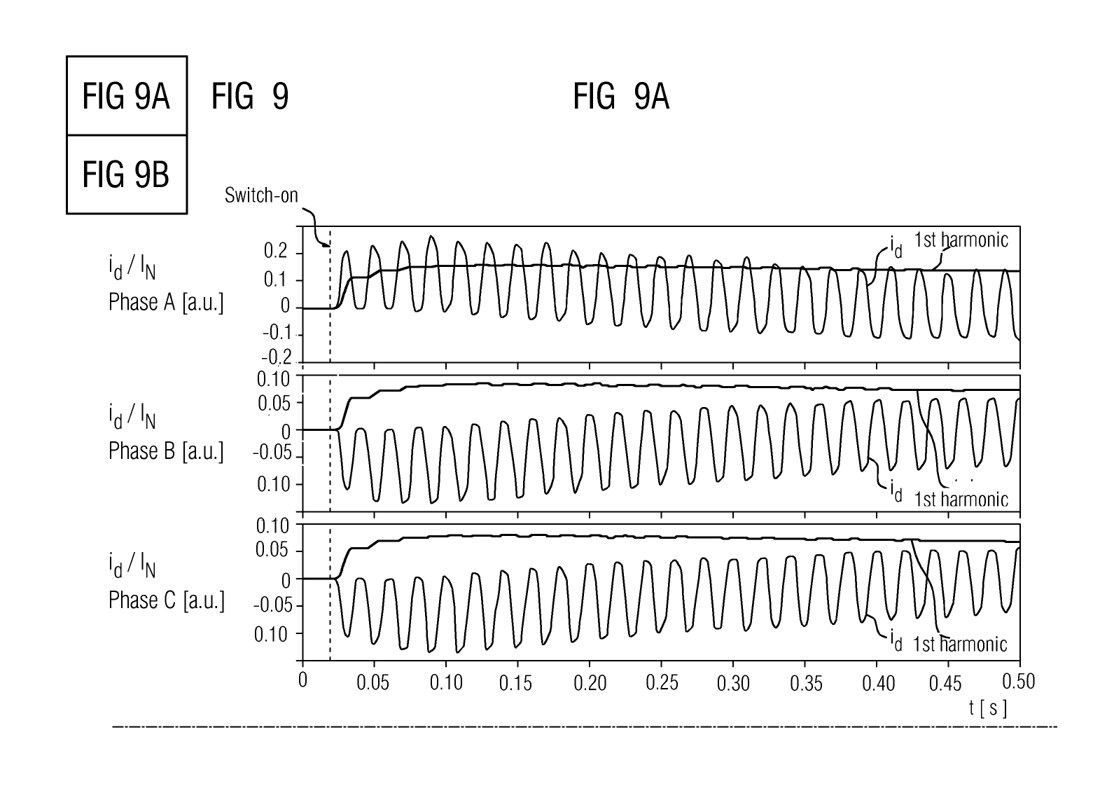

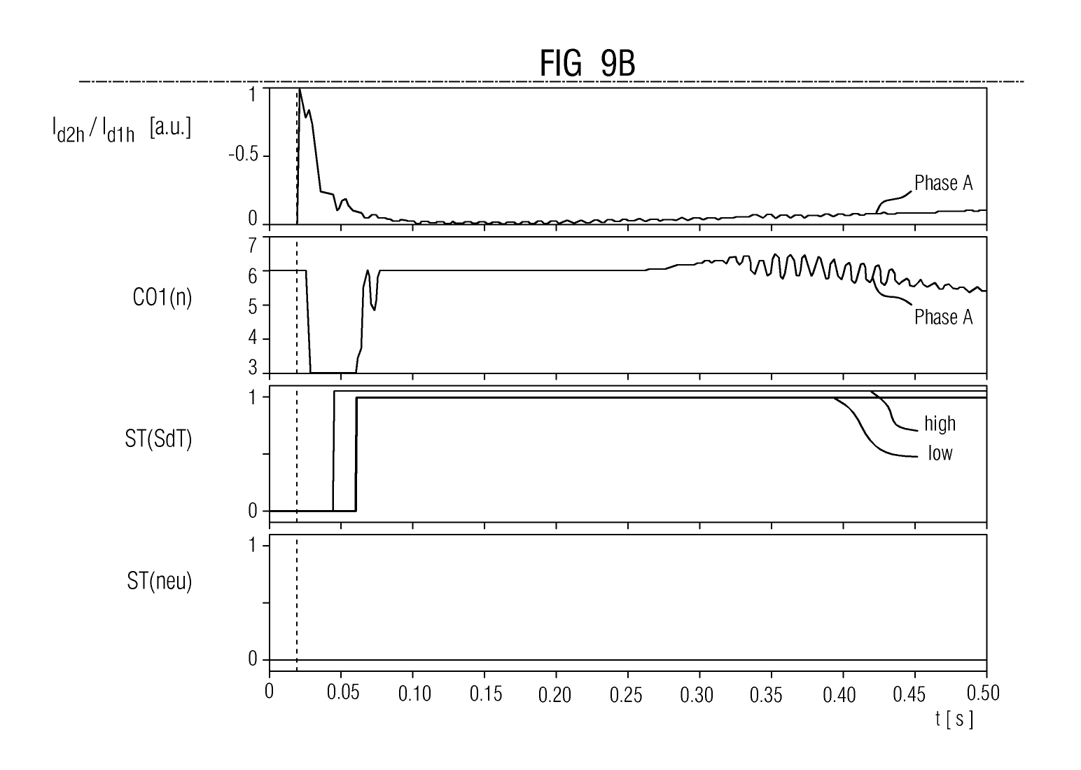

FIG. 9 shows the variation over time of the signals of the arrangement of FIG. 1,

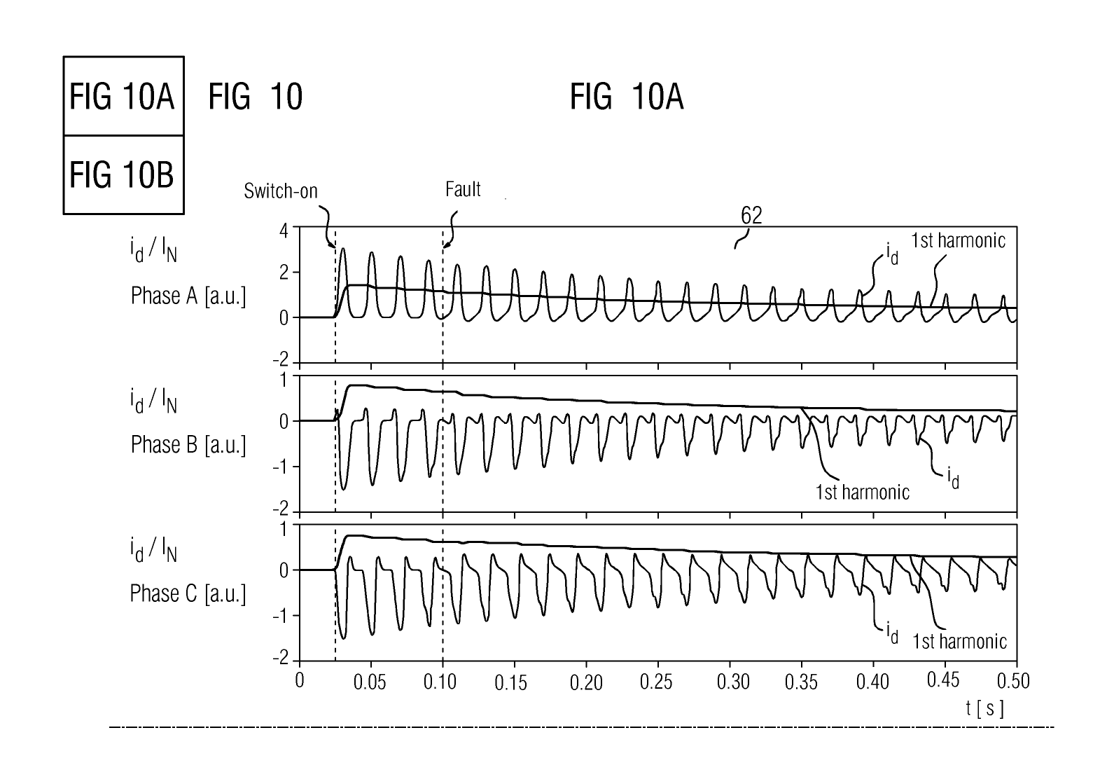

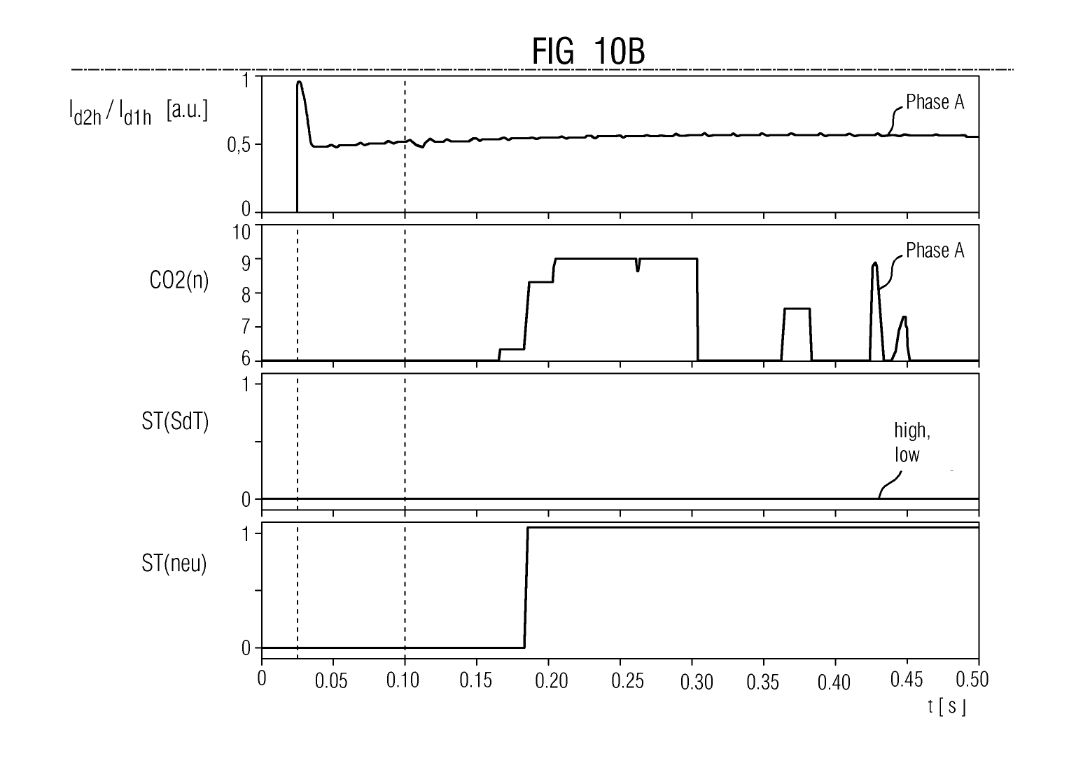

FIG. 10 shows further variations over time of the signals of the arrangement of FIG. 1.

For the sake of clarity, in the drawings, the same reference signs are used for any identical or comparable components. The exemplary embodiment of a method for generating a fault signal which is described in greater detail below enables stabilization of the transformer differential protection during the occurrence of magnetizing inrush currents; inter alia, the following steps which are described in greater detail below are preferably carried out:
generating differential current signals taking account of the input current signals (see block 11 in FIG. 1),
calculating criterion signals from the differential currents (see block 12 in FIG. 1),
defuzzification of the criterion signals (see block 13 in FIG. 1),
a fuzzy evaluation process which is divided into three independent decision paths and is based on pre-defined rules wherein fuzzy threshold values and fuzzified criterion signals are called upon (see block 14 in FIG. 1),
defuzzification of the final fuzzy result signals (see block 15 in FIG. 1),
a threshold value comparison (see blocks 16a, 16b and 16c in FIG. 1), and
generating a final fault signal (see block 17 in FIG. 1),

In the exemplary block circuit diagram of FIG. 1, a first block 11 is shown in which with the current sampling values i_{1A}(n), i_{1B}(n) and i_{1C}(n) on the primary side of the transformer and the current sampling values i_{2A}(n), I_{2B}(n) and i_{2C}(n) on the secondary side of the transformer, the corresponding differential currents i_{dA}(n), I_{dB}(n) and i_{dC}(n) are determined. In the next block 12, criterion signals (criterion values) K_{d1h}(n), K_{d2h}(n), K_{DCoff}(n), D_{1d}(n), K_{DCon}(n) and D_{2d}(n) are calculated. In the next block 13, fuzzification, as described below in greater detail in relation to the equations 32 to 49, is carried out.

Block 14 contains three result paths EP1, EP2 and EP3 in which all or some of the criterion values cited above are evaluated.

In the next block 15, the results are defuzzified and defuzzified decision signals CO₁(n), CO₂(n) and CO₃(n), which are each subjected to a threshold value comparison, are generated. The threshold value comparison is carried out in blocks 16a, 16b and 16c. As a result of the threshold value comparison, from the defuzzified decision signals CO₁(n), CO₂(n) and CO₃(n), logical binary signals CO1′ to CO3′ are generated. These signals pass to an OR gate 17 which generates the fault signal ST with a logical “1” if the conclusion is drawn that an internal transformer fault has occurred, and a logical “0” if no internal transformer fault is detected.

FIG. 2 shows, by way of example, a block circuit diagram in order to determine the DC components. In block 21, it is initially determined whether a “fault” has occurred although, at this time point, it is still undetermined whether it is only a switching-on process or an internal fault that has occurred. For this purpose, the differential current values i_{d}(n) are evaluated. For example, it is concluded that a “fault” has occurred if the differential current values i_{d}(n) exceed a predetermined threshold.

Subsequently, in a block 22, the value of a variable r is determined. In a subsequent block 23, the values Tₙ(n) and I_{dDC0}(n) are determined. The corresponding values are transferred to an evaluating block 24 in which the variable I_{dDCon}(n) is calculated. Furthermore, the values are transferred to a decision member 25 in which it is tested whether the respective sampling value n is smaller than the window length N+1. If this is the case, then the values for the variables I_{dDCoff}(n) are calculated in block 26. If the evaluation in block 25 produces the result that the comparison condition n<N+1 is not met, then the variable I_{dDCoff}(n) is calculated in block 27.

FIG. 3 shows a block circuit diagram for calculating the disturbance coefficients in the non-saturation interval. In block 31, the direction (or the sign) of the DC component is determined. In a subsequent block 32, the interval for the non-saturation is determined. In a subsequent block 33, the sampled values recorded are approximated and variables iₐₚᵣ₁ and iₐₚᵣ₂ are determined. The subsequent block 34 serves to determine the disturbance coefficients in the non-saturation interval. The deformation coefficients (disturbance coefficients) are identified in FIG. 3 as D_{1d} and D_{2d}.

FIG. 4 shows the extraction of the measurement results in the non-saturation interval taking account of the signal model according to equation 33 (see below).

FIG. 5 shows, in greater detail, the mode of operation of the first results path EP1 of FIG. 1 by way of example. In blocks 51 and 52, the fuzzy membership functions (fuzzified membership functions) μ_{L}(K_{d1h}(n)) . . . μ_{H}(K_{d2h}(n))₂ applied at the input side and previously generated in block 13 as per FIG. 1 by fuzzification from the corresponding input variables K_{d1h}(n)) . . . K_{d2h}(n), are evaluated and fuzzified intermediate signals MF1(x)(n) to MF10(x)(n) are generated, from which a fuzzified result signal MFₒᵤₜ₁(x)(n) is generated in block 53. By means of defuzzification and threshold value comparison, the logical binary signal CO1′ of the result path EP1 can be generated from the fuzzified decision signal MFₒᵤₜ₁(x)(n) as per FIG. 1.

FIG. 6 shows, by way of example, a block circuit diagram for the mode of operation of the second result path EP2 as per FIG. 1. The fuzzy membership functions μ_{L}(D_{1d}(n)) to μ_{H}(D_{1d}(n)) applied at the input side which have previously been generated in block 13 as per FIG. 1, are evaluated in blocks 61 and 62 and fuzzified intermediate signals MF11(x)(n) to MF16(x)(n) are generated, from which a fuzzified result signal MFₒᵤₜ₂(x)(n) is generated for the second result path EP2 in block 63. By means of defuzzification and threshold value comparison, the logical binary signal CO2′ of the second result path EP2 can be generated from the fuzzified decision signal MFₒᵤₜ₂(x)(n) as per FIG. 1.

FIG. 7 shows, by way of example, a block circuit diagram for the functioning of the third result path EP3 as per FIG. 1. The fuzzy membership functions μ_{L}(D_{2d}(n)) to μ_{H}(D_{2d}(n)) applied at the input side and previously generated in block 13 as per FIG. 1, are evaluated in block 71 and fuzzified intermediate signals MF17 (x)(n) to MF18 (x)(n) are generated, from which a fuzzified result signal MFₒᵤₜ₃(x)(n) is generated for the third result path EP3 in block 72 as per FIG. 1. By means of defuzzification and threshold value comparison, the logical binary signal CO3′ of the third result path EP3 as per FIG. 1 can be generated from the fuzzified result signal MFₒᵤₜ₃(x)(n).

FIG. 8 shows, by way of example, the defuzzification of the fuzzified results signals MFₒᵤₜ₁(x)(n) to MFₒᵤₜ₃(x)(n) generated by the result paths EP1, EP2 and EP3. It is apparent that, with the aid of the comparators 81, the logical binary signals CO1′ to CO3′ are generated, with which, using an OR operation 82, the fault signal ST is generated.

The mode of operation of the arrangement of FIG. 1 will now be considered in detail:

### Calculation of the Criterion Signals:

The criterion signals used are preferably calculated directly from the differential currents. In order to enable particularly reliable operation of the stabilization algorithm, the following criterion signals are preferably used:
the ratio K_{d1h} of the fundamental I_{d1h} to the nominal current Iₙ of the transformer (K_{d1h}=I_{d1h}/Iₙ),
the ratio Kᵣ₂ₕ of the second harmonic I_{d2h} to the fundamental I_{d1h} in the differential current (Kᵣ₂ₕ=I_{d2h}/I_{d1h}).
the ratio K_{dCoff} of the reconstructed DC component I_{rdCoff} to the fundamental I_{d1h} in the differential current (K_{DCoff}=I_{rDCoff}/I_{d1h}),
the ratio of the DC components which is calculated online based on I_{rdCon} and the fundamental I_{d1h} of the differential current (K_{DCon}=I_{rDCon}/I_{d1h}),
the deformation coefficient (disturbance coefficient) D_{1d} in the non-saturation time interval (hereinafter designated “non-saturation interval” of the differential current at small differential currents and
the deformation coefficient (disturbance coefficient) D_{2d} of the differential current in the non-saturation interval at large differential currents.

### Fundamental (Basic Wave) I_{d1h} and Second Harmonic I_{d2h} in the Differential Current:

In order to filter out the 50/100 Hz components, FIR filters (preferably Fourier filters), with which the orthogonal components which are used to calculate the size of the fundamental and of the second harmonic of the differential current are determined, are preferably used.

### DC Components in the Differential Current I_{dDC}:

The measuring algorithm for determining the DC components starts when a fault is detected. Identification of a fault can be carried out, for example, with a comparison of the actual current sampling values at the terminals of the transformer with corresponding current sampling values, which were detected N sampling values beforehand. The variable N denotes the window length in the form of a number of sampling values.

The DC components can be calculated with the aid of an algorithm based on the formation of a mean value of the current over a full cycle and thus on signal filtration with a zero-order Walsh filter. Accordingly, the averaged signal is a linear combination of actual sampling values of the differential current I_{d} and coefficients of the rectangular filter window (see FIG. 2, block 22):

$${i}_{dw 0} ( n ) = {\sum }_{k = 0}^{N - 1} {i}_{d} ( n - k ) \qquad ( 5 )$$

where I_{d} is the differential current. In the next step, the coefficient which carries the information concerning the time constant of the DC component is calculated:

$$r ( n ) = \frac{{i}_{dw 0} ( n )}{{i}_{dw 0} ( n - 1 )} \qquad ( 6 )$$

Once the coefficient r is known, it is possible to calculate the value for the time constant (see FIG. 2, block 23):

$${T}_{N} ( n ) = - \frac{{T}_{s}}{ln [ r ( n ) ]} \qquad ( 7 )$$

where Tₛ denotes the sampling period.

The starting value of the DC component is calculated as follows (see FIG. 2, block 23):

$${I}_{dDC 0} ( n ) = \frac{{i}_{dw 0} ( n )}{{\sum }_{k = 0}^{N - 1} {r ( n - k )}^{k}} {e}^{{nT}_{s}} \qquad ( 8 )$$

The values of the DC component at successive time points can be calculated in two ways. The first method is based on the calculation of the actual value of the DC component, wherein the actual values of the measured time constants and the starting values of the DC component are used:

$${I}_{dDCon} ( n ) = {I}_{dDC 0} ( n ) \cdot {e}^{\frac{n \cdot {T}_{s}}{{T}_{N} ( n )}} \qquad ( 9 )$$

The second method is based on the actual values of the time constant and the starting value of the DC component (as per Equation 9), only until the first potentially correct estimates of the starting value of the DC component and the time constants are known. From this moment on, the subsequent values of the DC component are reconstructed, making use of the first correct values of the DC component and the time constants, which can be expressed as follows:

$${I}_{dDCoff} ( n ) = \{ \begin{matrix}{I}_{dDC 0} ( n ) \cdot {e}^{- \frac{n \cdot {T}_{s}}{{T}_{N} ( n )}} & for n < N + 1 ; \\ {I}_{dDC 0} ( N + 1 ) \cdot {e}^{- \frac{n \cdot {T}_{s}}{{T}_{N} ( N + 1 )}} & for n \geq N + 1 ;\end{matrix} \qquad ( 10 )$$

where n=0 at the start of the estimation.

### Deformation Coefficients (Disturbance Coefficients) of the Differential Currents D_{1d} and D_{2d} in the Non-Saturation Interval:

The block circuit diagram according to FIG. 3 shows, by way of example, an estimation algorithm for determining the disturbance coefficients in the non-saturation interval. Calculation of the disturbance coefficients is carried out in four steps. In a first step (block 31), the direction or polarity of the DC component is obtained and two additional factors DCZ₁ and DCZ₂ are determined. With regard to the deformation coefficient (disturbance coefficient) D_{1d} which is utilized to identify internal low current faults, the DC component is calculated directly offline. If the variable I_{dDCoff} is positive, the factor DCZ₁=1, otherwise said factor=−1. With regard to the disturbance coefficient D_{2d}, which is used to increase speed, another approach is used:

$$\begin{matrix} If \vert {max}_{k = n - N + 1 , … , n} ( {i}_{d} ( k ) ) \vert > \vert {min}_{k = n - N + 1 , … , n} ( {i}_{d} ( k ) ) \vert \\ then & ( 11 ) \\ {DCZ}_{2} ( n ) = \{ \begin{matrix}1 & for & {K}_{p} \cdot \vert {max}_{k = n - N + 1 , … , n} ( {i}_{d} ( k ) ) \vert \geq \vert {min}_{k = n - N + 1 , … , n} ( {i}_{d} ( k ) ) \vert ; \\ - 1 & for & {K}_{p} \cdot \vert {max}_{k = n - N + 1 , … , n} ( {i}_{d} ( k ) ) \vert < \vert {min}_{k = n - N + 1 , … , n} ( {i}_{d} ( k ) ) \vert ;\end{matrix} \\ and if & ( 12 ) \\ \vert {min}_{k = n - N + 1 , … , n} ( {i}_{d} ( k ) ) \vert > \vert {max}_{k = n - N + 1 , … , n} ( {i}_{d} ( k ) ) \vert \\ then & ( 13 ) \\ {DCZ}_{2} ( n ) = \{ \begin{matrix}- 1 & for & {K}_{p} \cdot \vert {min}_{k = n - N + 1 , … , n} ( {i}_{d} ( k ) ) \vert \geq \vert {max}_{k = n - N + 1 , … , n} ( {i}_{d} ( k ) ) \vert ; \\ 1 & for & {K}_{p} \cdot \vert {min}_{k = n - N + 1 , … , n} ( {i}_{d} ( k ) ) \vert < \vert {max}_{k = n - N + 1 , … , n} ( {i}_{d} ( k ) ) \vert ;\end{matrix} & ( 14 )\end{matrix}$$

where Kₚ is a predetermined coefficient.

In the next step, detection of the non-saturation interval is carried out (see block 32 in FIG. 3). In order to detect the local sampling sequence of the non-saturation time span, the differential current (see FIG. 4, section a) is observed within the data window which is made up of 3/2 N sampling values (see FIG. 4, section b), where N is the number of the window in one cycle of the fundamental. Along a data window of this type, a further local window which consists of N/2−1 sampling values is moved in a sequence beginning from the main observation window. In this window, the N+2 sum of N/2−1 sequential sampling values of the signal under observation is calculated as follows:

$${S}_{l} ( n ) = {\sum }_{k = 0}^{N / 2 - 2} {i}_{d} ( n + k - 3 / 2 N + l ) \\ where \\ l = 1 , … , N + 2 \qquad ( 15 )$$

If the factor DCZ_{1,2}=1, then the local window with the minimum sum, calculated according to Equation 24, is selected, as shown in FIG. 4, section c). Otherwise, that is, if the factor DCZ_{1,2}=−1, the local window with the maximum sum is selected. The detected local windows are additionally defined as original sampling sequences i_{org1} and i_{org2}, and in order to protect the algorithm against unwanted errors, the local window is only taken into account if the absolute value of the difference between the minimum value and the maximum value in the detected local window is greater than 2% of the transformer nominal current:

$$\begin{matrix}If \vert {min}_{k = 1 , … , 9} ( {i}_{org 1} ( k ) ( n ) ) - {max}_{k = 1 , … , 9} ( {i}_{org 1} ( k ) ( n ) ) \vert < 0.02 \cdot {I}_{n} \\ then & ( 16 ) \\ {D}_{r} ( n ) = DX & ( 17 )\end{matrix}$$

where DX is a pre-determined constant value.

If the sampling values of the first and last samples of the local window being recorded are not simultaneously minimum and maximum values, the following applies:

$$\begin{matrix}If {max}_{k = 1 , … , N / 2 - 1} ( {i}_{org 1} ( k ) ( n ) ) = {i}_{org 1} ( 1 ) ( n ) \\ and & ( 18 ) \\ {min}_{k = 1 , … , N / 2 - 1} ( {i}_{org 1} ( k ) ( n ) ) = {i}_{org 1} ( N / 2 - 1 ) ( n ) \\ then & ( 19 ) \\ {D}_{r} ( n ) = DX \\ or , if & ( 20 ) \\ {min}_{k = 1 , … , N / 2 - 1} ( {i}_{org 1} ( k ) ( n ) ) = {i}_{org 1} ( 1 ) ( n ) \\ and & ( 21 ) \\ {max}_{k = 1 , … , N / 2 - 1} ( {i}_{org 1} ( k ) ( n ) ) = {i}_{org 1} ( N / 2 - 1 ) ( n ) \\ then & ( 22 ) \\ {D}_{r} ( n ) = DX & ( 23 )\end{matrix}$$

The first condition protects the algorithm against evaluating a signal having only a small portion of usable information. The second condition helps to avoid a situation where an almost linear waveform is detected. This is possible if, during the switching on of the transformer, current transformer saturation occurs. In this way, the values of the disturbance coefficient can be reduced.

In the next step, the original sampling sequences i_{org1} and i_{org2} are approximated (see block 33 in FIG. 3). The “least squares” approximation of the original signal was used for the following signal model:

i_{d}(k)=Iₛ·sin(2·πf₁·Tₚ·k)+I_{c}·cos(2·πf₁·Tₚ·k) (24)

i_{d}(k)=I_{DC}+Iₛ·sin(2·π·f₁·Tₚ·k)+I_{c}·cos(2·π·f₁·Tₚ·k) (25)

The model according to Equation 24 is used in order to improve fault detection in winding-to-winding faults with small currents and, as a result of the approximation, to obtain the sampling sequence iₐₚₚᵣ₁ as follows:

iₐₚₚᵣ₁(n)=H₁·M_{coff}(n) (26)

wherein H₁ is a coefficient matrix of the signal model used, according to Equation 24, and

M_{coff}(n)=((H₁^{T}·H₁)⁻¹)·H₁^{T}·i_{org1}(n) (27)

The second model according to Equation 25 is used in order to accelerate the processing of the proposed algorithm in the case of internal faults with large and long-lasting DC components in the differential current and, as a result of the approximation, to obtain the sampling sequence iₐₚₚᵣ₁ as follows:

iₐₚₚᵣ₂(n)=H₂·M_{coff}(n) (28)

wherein H₂ is a coefficient matrix of the signal model used, according to Equation 25, and the following applies:

M_{coff}(n)=((H₂^{T}·H₂)⁻¹)·H₂^{T}·i_{org 2}(n) (29)

In the last phase in which signals are obtained from the estimating process, the disturbance coefficients are calculated as follows (see block 34 in FIG. 3):

$$\begin{matrix}{D}_{1 d} = \frac{{\sum }_{k = 1}^{N / 2 - 1} \vert {i}_{appr 1} ( k ) - {i}_{org 1} ( k ) \vert}{\frac{1}{N / 2 - 1} {\sum }_{k = 1}^{N / 2 - 1} \vert {i}_{org 1} ( k ) \vert} & ( 30 ) \\ {D}_{2 d} = \frac{{\sum }_{k = 1}^{N / 2 - 1} \vert {i}_{appr 2} ( k ) - {i}_{org 2} ( k ) \vert}{\frac{1}{N / 2 - 1} {\sum }_{k = 1}^{N / 2 - 1} \vert {i}_{org 2} ( k ) \vert} & ( 31 )\end{matrix}$$

The smaller the disturbance coefficient, the more probable is the hypothesis of an internal fault. If the fragment of the differential current as detected is identical to the approximation thereof, then the disturbance coefficient is equal to 0 and it can be taken without doubt that an internal fault has occurred. In section d) of FIG. 4, the pattern of the disturbance coefficient in the non-saturation interval, as calculated according to Equation 30 is shown during the switching on of a problem-free transformer with current transformer saturation. It is shown that the deformation coefficient (disturbance coefficient) D_{1d} does not reach the value 0 (the value exceeds 1 throughout the entire simulation), which supports the assumption of a switching-on process of the transformer.

### Fuzzification of the Criterion Signals:

In this block, the measured criterion signals are fuzzified. As a result of the fuzzification process, the criterion signals (input signals of the fuzzification block) are converted into logic signals μ_{L}, μ_{M} and μ_{H} (output signals of the fuzzification block, in this case named fuzzy membership functions). The fuzzification therefore maps the actual measured criterion signals to a suitable fuzzy set. This can be formalized in the following way:

### Fuzzification of the Criterion Value K_{d1h}:

$$\begin{matrix}{μ}_{L} ( {K}_{d 1 h} ( n ) ) = \{ \begin{matrix}1 & if & {K}_{d 1 h} ( n ) < FI 1 L 1 \\ \frac{FI 1 L 2 - {K}_{d 1 h} ( n )}{FI 1 L 2 - FI 1 L 1} & if & FI 1 L 1 \leq {K}_{d 1 h} ( n ) \leq FI 1 L 2 \\ 0 & if & {K}_{d 1 h} ( n ) > FI 1 L 2\end{matrix} & ( 32 ) \\ {μ}_{M} ( {K}_{d 1 h} ( n ) ) = \{ \begin{matrix}0 & if & {K}_{d 1 h} ( n ) < FI 1 M 1 \\ \frac{{K}_{d 1 h} ( n ) - FI 1 M 1}{FI 1 M 2 - FI 1 M 1} & if & FI 1 M 1 \leq {K}_{d 1 h} ( n ) \leq FI 1 M 2 \\ 1 & if & FI 1 M 2 \leq {K}_{d 1 h} ( n ) \leq FI 1 M 3 \\ \frac{FI 1 M 4 - {K}_{d 1 h} ( n )}{FI 1 M 4 - FI 1 M 3} & if & FI 1 M 3 \leq {K}_{d 1 h} ( n ) \leq FI 1 M 4 \\ 0 & if & {K}_{d 1 h} ( n ) > FI 1 M 4\end{matrix} & ( 33 ) \\ {μ}_{H} ( {K}_{d 1 h} ( n ) ) = \{ \begin{matrix}0 & if & {K}_{d 1 h} ( n ) < FI 1 H 1 \\ \frac{{K}_{d 1 h} ( n ) - FI 1 H 1}{FI 1 H 2 - FI 1 H 1} & if & FI 1 H 1 \leq {K}_{d 1 h} ( n ) \leq FI 1 H 2 \\ 1 & if & {K}_{d 1 h} ( n ) > FI 1 H 2\end{matrix} & ( 34 )\end{matrix}$$

where the following can apply:

### FI1L1=0.02·Iₙ; FI1L2=0.05·Iₙ

### FI1M1=0.02·Iₙ; FI1M2=0.05·Iₙ; FI1M3=0.95 Kᵢₙ Iₙ; FI1M4=Kᵢₙ·Iₙ

### FI1H1=0.95 Kᵢₙ·Iₙ; FI1H2=Kᵢₙ·Iₙ

Kᵢₙ describes a value of the maximum expected surge current which relates to the nominal current of the protected transformer.

### Fuzzification of the Criterion Value K_{d2h}:

$$\begin{matrix}{{μ}_{L} ( {K}_{d 2 h} ( n ) )}_{1} = \{ \begin{matrix}1 & if & {K}_{d 2 h} ( n ) < FI 2 L 1 \\ \frac{FI 2 L 2 - {K}_{d 2 h} ( n )}{FI 2 L 2 - FI 2 L 1} & if & FI 2 L 1 \leq {K}_{d 2 h} ( n ) \leq FI 2 L 2 \\ 0 & if & {K}_{d 2 h} ( n ) > FI 2 L 2\end{matrix} & ( 35 ) \\ {{μ}_{H} ( {K}_{d 2 h} ( n ) )}_{1} = \{ \begin{matrix}0 & if & {K}_{d 2 h} ( n ) < FI 2 H 1 \\ \frac{{K}_{d 2 h} ( n ) - FI 2 H 1}{FI 2 H 2 - FI 2 H 1} & if & FI 2 H 1 \leq {K}_{d 2 h} ( n ) \leq FI 2 H 2 \\ 1 & if & {K}_{d 2 h} ( n ) > FI 2 H 2\end{matrix} & ( 36 )\end{matrix}$$

where the following can apply:

### FI2L1=0.05; FI2L2=0.1

### FI2H1=0.05; FI2H2=0.1.

### Fuzzification of the Criterion Value K_{DCoff}:

$$\begin{matrix}{μ}_{L} ( {K}_{DCoff} ( n ) ) = \{ \begin{matrix}1 & if & {K}_{DCoff} ( n ) < FI 3 L 1 \\ \frac{FI 3 L 2 - {K}_{DCoff} ( n )}{FI 3 L 2 - FI 3 L 1} & if & FI 3 L 1 \leq {K}_{DCoff} ( n ) \leq FI 3 L 2 \\ 0 & if & {K}_{DCoff} ( n ) > FI 3 L 2\end{matrix} & ( 37 ) \\ {μ}_{H} ( {K}_{DCoff} ( n ) ) = \{ \begin{matrix}0 & if & {K}_{DCoff} ( n ) < FI 3 H 1 \\ \frac{{K}_{DCoff} ( n ) - FI 3 H 1}{FI 3 H 2 - FI 3 H 1} & if & FI 3 H 1 \leq {K}_{DCoff} ( n ) \leq FI 3 H 2 \\ 1 & if & {K}_{DCoff} ( n ) > FI 3 H 2\end{matrix} & ( 38 )\end{matrix}$$

where the following can apply:

### FI3L1=0.5; FI3L2=0.55

### FI3H1=0.5; FI3H2=0.55

### Fuzzification of the Criterion Value K_{d2h}:

$$\begin{matrix}{{μ}_{L} ( {K}_{d 2 h} ( n ) )}_{2} = \{ \begin{matrix}1 & if & {K}_{d 2 h} ( n ) < FI 4 L 1 \\ \frac{FI 4 L 2 - {K}_{d 2 h} ( n )}{FI 4 L 2 - FI 4 L 1} & if & FI 4 L 1 \leq {K}_{d 2 h} ( n ) \leq FI 4 L 2 \\ 0 & if & {K}_{d 2 h} ( n ) > FI 4 L 2\end{matrix} & ( 39 ) \\ {{μ}_{H} ( {K}_{d 2 h} ( n ) )}_{2} = \{ \begin{matrix}0 & if & {K}_{d 2 h} ( n ) < FI 4 H 1 \\ \frac{{K}_{d 2 h} ( n ) - FI 4 H 1}{FI 4 H 2 - FI 4 H 1} & if & FI 4 H 1 \leq {K}_{d 2 h} ( n ) \leq FI 4 H 2 \\ 1 & if & {K}_{d 2 h} ( n ) > FI 4 H 2\end{matrix} & ( 40 )\end{matrix}$$

where the following can apply:

### FI4L1=0.37; FI4L2=0.43

### FI4H1=0.37; FI4H2=0.43

### Fuzzification of the Criterion Value D_{1d}:

$$\begin{matrix}{μ}_{L} ( {D}_{1 d} ( n ) ) = \{ \begin{matrix}1 & if & {D}_{1 d} ( n ) < FI 5 L 1 \\ \frac{FI 5 L 2 - {D}_{1 d} ( n )}{FI 5 L 2 - FI 5 L 1} & if & FI 5 L 1 \leq {D}_{1 d} ( n ) \leq FI 5 L 2 \\ 0 & if & {D}_{1 d} ( n ) > FI 5 L 2\end{matrix} & ( 41 ) \\ {μ}_{M} ( {D}_{1 d} ( n ) ) = \{ \begin{matrix}0 & if & {D}_{1 d} ( n ) < FI 5 M 1 \\ \frac{{D}_{1 d} ( n ) - FI 5 M 1}{FI 5 M 2 - FI 5 M 1} & if & FI 5 M 1 \leq {D}_{1 d} ( n ) \leq FI 5 M 2 \\ 1 & if & FI 5 M 2 \leq {D}_{1 d} ( n ) \leq FI 5 M 3 \\ \frac{FI 5 M 4 - {D}_{1 d} ( n )}{FI 5 M 4 - FI 1 M 3} & if & FI 5 M 3 \leq {D}_{1 d} ( n ) \leq FI 5 M 4 \\ 0 & if & {D}_{1 d} ( n ) > FI 5 M 4\end{matrix} & ( 42 ) \\ {μ}_{H} ( {D}_{1 d} ( n ) ) = \{ \begin{matrix}0 & if & {D}_{1 d} ( n ) < FI 5 H 1 \\ \frac{{D}_{1 d} ( n ) - FI 5 H 1}{FI 5 H 2 - FI 5 H 1} & if & FI 5 H 1 \leq {D}_{1 d} ( n ) \leq FI 5 H 2 \\ 1 & if & {D}_{1 d} ( n ) > FI 5 H 2\end{matrix} & ( 43 )\end{matrix}$$

where the following can apply:

### FI5L1=0.9; FI5L2=1.0

### FI5M1=0.9; FI5M2=1.0; FI5M3=3.0; FI5M4=3.5

### FI5H1=3.0; FI5H2=3.5

### Fuzzification of the Criterion Value K_{d2h}:

$$\begin{matrix}{{μ}_{L} ( {K}_{d 2 h} ( n ) )}_{3} = \{ \begin{matrix}1 & if & {K}_{d 2 h} ( n ) < FI 6 L 1 \\ \frac{FI 6 L 2 - {K}_{d 2 h} ( n )}{FI 6 L 2 - FI 6 L 1} & if & FI 6 L 1 \leq {K}_{d 2 h} ( n ) \leq FI 6 L 2 \\ 0 & if & {K}_{d 2 h} ( n ) > FI 6 L 2\end{matrix} & ( 44 ) \\ {{μ}_{H} ( {K}_{d 2 h} ( n ) )}_{3} = \{ \begin{matrix}0 & if & {K}_{d 2 h} ( n ) < FI 6 H 1 \\ \frac{{K}_{d 2 h} ( n ) - FI 6 H 1}{FI 6 H 2 - FI 6 H 1} & if & FI 6 H 1 \leq {K}_{d 2 h} ( n ) \leq FI 6 H 2 \\ 1 & if & {K}_{d 2 h} ( n ) > FI 6 H 2\end{matrix} & ( 45 )\end{matrix}$$

where the following can apply:

### FI6L1=0.4; FI6L2=0.5

### FI6H1=0.4; FI6H2=0.5

### Fuzzification of the Criterion Value K_{DCon}:

$$\begin{matrix}{μ}_{L} ( {K}_{DCon} ( n ) ) = \{ \begin{matrix}1 & if & {K}_{DCon} ( n ) < FI 7 L 1 \\ \frac{FI 7 L 2 - {K}_{DCon} ( n )}{FI 7 L 2 - FI 7 L 1} & if & FI 7 L 1 \leq {K}_{DCon} ( n ) \leq FI 7 L 2 \\ 0 & if & {K}_{DCon} ( n ) > FI 7 L 2\end{matrix} & ( 46 ) \\ {μ}_{H} ( {K}_{DCon} ( n ) ) = \{ \begin{matrix}0 & if & {K}_{DCon} ( n ) < FI 7 H 1 \\ \frac{{K}_{DCon} ( n ) - FI 7 H 1}{FI 7 H 2 - FI 7 H 1} & if & FI 7 H 1 \leq {K}_{DCon} ( n ) \leq FI 7 H 2 \\ 1 & if & {K}_{DCon} ( n ) > FI 7 H 2\end{matrix} & ( 47 )\end{matrix}$$

where the following can apply:

### FI7L1=0.55; FI7L2=0.6

### FI7H1=0.55; FI7H2=0.6

### Fuzzification of the Criterion Value D_{2d}:

$$\begin{matrix}{μ}_{L} ( {D}_{2 d} ( n ) ) = \{ \begin{matrix}1 & if & {D}_{2 d} ( n ) < FI 8 L 1 \\ \frac{FI 8 L 2 - {D}_{2 d} ( n )}{FI 8 L 2 - FI 8 L 1} & if & FI 8 L 1 \leq {D}_{2 d} ( n ) \leq FI 8 L 2 \\ 0 & if & {D}_{2 d} ( n ) > FI 8 L 2\end{matrix} & ( 48 ) \\ {μ}_{H} ( {D}_{2 d} ( n ) ) = \{ \begin{matrix}0 & if & {D}_{2 d} ( n ) < FI 8 H 1 \\ \frac{{D}_{2 d} ( n ) - FI 8 H 1}{FI 8 H 2 - FI 8 H 1} & if & FI 8 H 1 \leq {D}_{2 d} ( n ) \leq FI 8 H 2 \\ 1 & if & {D}_{2 d} ( n ) > FI 8 H 2\end{matrix} & ( 49 )\end{matrix}$$

where the following can apply:

### FI8L1=0.15; FI8L2=0.2

### FI8H1=0.15; FI8H2=0.2

### Fuzzy Evaluation Process:

The fuzzy evaluation determines the fuzzy intermediate signals MFₒᵤₜ₁(x)(n) to MFₒᵤₜ₃(x)(n), wherein the pre-determined fuzzy rules and the fuzzy membership functions μ_{L}, μ_{H} and μ_{M} are used. In order to enable an interference process, for example, a max-product method can be used. The interference process takes place in three parallel result paths:

Result path EP1 as per FIG. 1 ensures the maximum safety. The interference process, as performed in result path 1, is shown by way of example in FIG. 5.

Result path EP2 as per FIG. 1 improves identification of low current winding faults. The interference process, as realized in result path EP2 as per FIG. 1, is shown in greater detail by way of example in FIG. 6.

Result path EP3 as per FIG. 1 is responsible for the speed increase during operation with an internal fault (although current transformer saturation usually occurs). The interference process, as realized in the third result path as per FIG. 1, is shown in greater detail in FIG. 7.

### Defuzzification of the Final Fuzzy Result Signals:

As a result of the defuzzification, the final fuzzified result signals MFₒᵤₜ(x)(n) are converted into “fresh” (actual) values CO(n). For the defuzzification, for example, a “center-of-the-region” method can be used, as performed in block 80 of FIG. 8.

### Determination of the Intermediate Indicators for the Transformer State:

At the output of the fuzzy system, three fresh (actual) values CO₁(n), CO₂(n) and CO₃(n) (see FIG. 8) are obtained. The location of this value in the domain of the final output fuzzy set determines the state of the protective operation. These values are then compared with the selected threshold values which can be, for example, 7.5 (see FIG. 8, block 81). If the threshold value is exceeded, a trigger signal is generated.

The size of the threshold values can be altered, wherein 7.5 is considered to be an optimum value. If the value is increased, then a higher level of safety can be achieved, whereas if the value is reduced, the system stability is improved.

### Formation of the Final Fault Signal ST:

The results of the comparison as carried out in block 81 as per FIG. 8 are brought together and an OR logic element 82 is used and generates the final decision in the form of a fault signal ST.

### Exemplary Signal Forms:

FIGS. 9 and 10 show, by way of example, the functioning of the arrangement as per FIG. 1. In FIGS. 9 and 10, the result of the function of the method according to FIG. 1 is compared with traditional methods which evaluate the second harmonic and make use of threshold values of 10% and 20%.

FIG. 9 shows the switching on of a transformer with a saturation effect: Shown here are the time values of the differential current i_{d} for all three phases, the ratio of the second harmonic I_{d2h} to the fundamental I_{d1h}, the fresh intermediate value CO₁(n), the resulting signal ST(SdT) for the differential protection with traditional stabilization and the resulting signal ST(neu) of the differential protection according to the method as per FIGS. 1 to 8. FIG. 9 shows that the waveforms of the differential currents are very similar to those which occur in the case of an internal fault. As a consequence, the proportion of the second harmonic is very low and, for some of the time, falls below a pre-determined threshold value (e.g. “0”). In a case of this type, the traditional stabilization fails entirely, regardless of threshold values and the transformer would be switched off (see resulting signal ST(SdT) in FIG. 9). If, however, the stabilization method as per FIGS. 1 to 8 is utilized, then it can be seen in FIG. 9 that the intermediate signal value CO₁(n) does not overshoot the value 7.5, thereby guaranteeing reliable stabilization in this situation (see signal form ST(neu) in FIG. 9) and prevents generation of a fault signal with a logical “1”.

FIG. 10 shows the corresponding signal form in the event of an internal winding fault in the transformer. The signals have been monitored during switching on with an internal winding fault and are displayed with a time resolution of 100 ms. Since the winding fault concerns only a single winding of the transformer, the influence thereof on the differential current i_{d} is almost undetectable. In traditional signal evaluation based on the second harmonic, the differential protection will fail.

However, the algorithm shown in relation to FIGS. 1 to 8 correctly identifies the internal fault due to the deformation coefficient (disturbance coefficient) D_{1d}. The intermediate decision signal CO2(n) exceeds the threshold value thereof of 7.5 84 ms after occurrence of the fault, so that the transformer is switched off (see decision signal ST(neu) in FIG. 10).

Summarizing, the multi-criterion fuzzy logic method as per FIGS. 1 to 8 has a series of advantages in relation to traditional stabilization methods, and this can be summarized as follows:
high degree of reliability (no false triggering of the protection regardless of the proportion of the second harmonic in the differential currents),
independence from current transformer saturation during magnetizing inrush current of the transformer,
shorter fault recognition time in the case of internal high current fields, and
greater sensitivity in the case of internal low current faults (e.g. in the case of winding faults, which affect only one winding of the transformer).

Although the invention has been illustrated and described in detail based on the preferred exemplary embodiment, the invention is not restricted by the examples given and other variations can be derived therefrom by a person skilled in the art without departing from the protective scope of the invention.

1-9. (canceled)

10. A method for generating a fault signal indicating whether an internal transformer fault has occurred, which comprises the steps of:
ascertaining a differential current signal indicating a difference between a primary current and, taking account of a conversion ratio of a transformer, a secondary current of the transformer;
generating a plurality of different criterion signals from the differential current signal;
assigning at least two individual fuzzy membership functions to each of the criterion signals; and
evaluating the fuzzy membership functions resulting in a generation of the fault signal.

11. The method according to claim 10, which further comprises:
forming at least three result paths and assigning to each of the three result paths at least one of the individual fuzzy membership functions;
evaluating the individual fuzzy membership functions in each of the three result paths, thereby generating a logical binary signal, wherein the logical binary signal indicates, according to a test result of a respective decision path, whether the internal transformer fault has occurred or not; and
subjecting logical binary signals to a logical operation, thereby generating the fault signal.

12. The method according to claim 11, which further comprises generating the fault signal by means of a logical OR operation with the logical binary signals.

13. The method according to claimed in claim 11,
wherein at least the individual fuzzy membership functions of a respective one of the criterion signals are also assigned to at least one of the result paths, the respective criterion signal relating to a ratio of a fundamental of a differential current to a nominal current of the transformer; and
which further comprises generating the logical binary signal of the result path with the individual fuzzy membership functions.

14. The method according to claim 11, which further comprises:
assigning at least the individual fuzzy membership functions of a criterion signal to at least one of the result paths, the criterion signal relating to a deformation coefficient (disturbance coefficient) of a differential current in a non-saturation time interval of the differential current at small differential currents; and
generating the logical binary signal of the result path with the fuzzy membership functions.

15. The method according to claim 10, which further comprises:
assigning at least the fuzzy membership functions of a criterion signal also to at least one of the result paths, the criterion signal relating to a deformation coefficient of a differential current in a non-saturation time interval of the differential current for a rapid fault detection at large differential currents; and
generating the logical binary signal of the result path with the individual fuzzy membership functions.

16. The method according to claim 11, which further comprises:
using at least three of the result paths and assigning to each of the result paths at least one of the individual fuzzy membership functions;
assigning at least the individual fuzzy membership functions of the criterion signals to a first result path, the criterion signal relating to at least one of a ratio of a fundamental of a differential current to a nominal current of the transformer, to a ratio of a 2nd harmonic to the fundamental in the differential current or to a ratio of a reconstructed DC component to the fundamental in the differential current and a first logical binary signal of the first result path is generated with the individual fuzzy membership functions;
assigning at least the individual fuzzy membership functions of the criterion signals to a second result path, the criterion signals relating to at least one of a deformation coefficient of the differential current in a non-saturation time interval of the differential current at small differential currents or to the deformation coefficient of the differential current in the non-saturation time interval of the differential current for detecting winding faults at small differential currents, and a second logical binary signal of the second result path is generated with the individual fuzzy membership functions; and
assigning at least the fuzzy membership functions of a criterion signal to a third result path, the criterion signal relating to the deformation coefficient of the differential current in the non-saturation time interval of the differential current for a rapid fault detection at large differential currents, and a third logical binary signal of the third result path is generated with the individual fuzzy membership functions.

17. The method according to claim 16, which further comprises generating the fault signal by a logical OR operation with the first, second and third logical binary signals.

18. A differential protection device for protecting a transformer, the differential protection device comprising:
a computer device;
a memory store;
a program for controlling said computer device being stored in said memory store, and during execution by said computer device, said program executing a method for generating a fault signal indicating whether an internal transformer fault has occurred, said program performing the steps of:
ascertaining a differential current signal indicating a difference between a primary current and, taking account of a conversion ratio of the transformer, a secondary current of the transformer;
generating a plurality of different criterion signals from the differential current signal;
assigning at least two individual fuzzy membership functions to each of the criterion signals; and
evaluating the fuzzy membership functions resulting in a generation of the fault signal.
